(19) United States
(12) Patent Application Publication
(10) Pub. No.: US 2019/0085853 A1
(43) Pub. Date: Mar. 21, 2019

(54) FAN

(71) Applicant: Delta Electronics, Inc., Taoyuan City (TW)

(72) Inventors: Shun-Chen CHANG, Taoyuan City (TW); Wen-Bin LIU, Taoyuan City (TW); Tien-Kun LIN, Taoyuan City (TW); Chao-Fu YANG, Taoyuan City (TW)

(21) Appl. No.: 15/866,016

(22) Filed: Jan. 9, 2018

(30) Foreign Application Priority Data
Sep. 18, 2017 (CN) 201710840601.7

(51) Int. Cl. F04D 25/08; F04D 29/60; H05K 7/20; F04D 19/04; F04D 29/18

(52) U.S. Cl. CPC F04D 25/082; F04D 29/602; F04D 29/181; F04D 19/048; H05K 7/20172

(57) ABSTRACT

A fan is provided. The fan includes a frame, a rotor and a stator. The rotor is received in the frame and includes a magnetic part, a metal housing, a hub and a plurality of blades. The metal housing is telescoped on the magnetic part. The hub is telescoped on the metal housing. The blades are formed on the hub. The stator is received in the frame. The stator includes a plurality of silicon-steel sheets which form a silicon-steel sheet outside diameter, the silicon-steel sheet outside diameter is greater than 42 mm and wherein the rated speed of the fan is greater than 8000 RPM.

### CROSS REFERENCE TO RELATED APPLICATIONS

This Application claims priority of China Patent Application No. 201710840601.7, filed on Sep. 18, 2017, the entirety of which is incorporated by reference herein.

### BACKGROUND OF THE INVENTION

### Field of the Invention

The present invention relates to a fan, and in particular to a fan which has improved efficiency.

### Description of the Related Art

With the increased computing performance of computers and servers, the heat dissipation requirements are gradually becoming much strict. The convection efficiency of a conventional small-sized fan, such as a fan with dimensions smaller than 120 mm×120 mm, cannot satisfy these heat dissipation requirements. The greatest power consumption or efficiency of such a small-sized fan is less than 200 W under even its highest speed. Additionally, a conventional large-sized fan, such as a fan with dimensions greater than 170 mm×150 mm, also cannot be utilized in such applications due to the limited space inside computers and servers.

Conventionally, fans are arranged in series or on opposite sides to increase convection efficiency. However, these kinds of arrangements of fans increase the cost and the size of the fan module. Therefore, a fan with improved efficiency and performance is required.

### BRIEF SUMMARY OF THE INVENTION

In one embodiment, a fan is provided. The fan includes a frame, a rotor and a stator. The rotor is received in the frame and includes a magnetic part, a metal housing, a hub and a plurality of blades. The metal housing is telescoped on the magnetic part. The hub is telescoped on the metal housing. The blades are formed on the hub. The stator is received in the frame. The stator includes a plurality of silicon-steel sheets, wherein the silicon-steel sheets form a silicon-steel sheet outside diameter, the silicon-steel sheet outside diameter is greater than 42 mm and the rated speed of the fan is greater than 8000 RPM.

In one embodiment, the frame comprises a first edge and a second edge. The first edge is perpendicular to the second edge. The first and the second edges are located on a plane. An axial direction of the fan is perpendicular to the plane. The first edge has a first width and the second edge has a second width. The first width is between 131 mm and 139 mm, and the second width is between 131 mm and 139 mm.

In one embodiment, the frame has a frame height in an axial direction of the fan, the silicon-steel sheet has a silicon-steel sheet height in the axial direction of the fan, and the ratio of the silicon-steel sheet height to the frame height is between 0.26 and 0.4.

In one embodiment, the frame forms a flow path, the flow path has a path diameter, and the ratio of the silicon-steel sheet outside diameter to the path diameter is between 0.4 and 0.5.

In one embodiment, the hub has a hub diameter, the metal housing has a metal housing height in the axial direction of the fan, the ratio of the hub diameter to the path diameter is between 0.53 and 0.63, and the ratio of the metal housing height to the frame height is between 0.5 and 0.6.

In one embodiment, the metal housing has a metal housing inside diameter, and the ratio of the metal housing inside diameter to the path diameter is between 0.45 and 0.55.

In one embodiment, the thickness of the blade is between 3 mm and 4.5 mm.

In one embodiment, the material thickness of the hub is between 2 mm and 3 mm.

In one embodiment, the frame comprises a plurality of ribs or a plurality of static blades, and the greatest thickness among the ribs or the static blades is greater than 1.5 mm.

In another embodiment, a fan is provided. The fan includes a frame, a rotor and a stator. The rotor is received in the frame and includes a magnetic part, a metal housing, a hub, and a plurality of blades. The metal housing is telescoped on the magnetic part. The hub is telescoped on the metal housing. The blades are formed on the hub. The stator is received in the frame, comprising a plurality of silicon-steel sheets, wherein the frame has a frame height in an axial direction of the fan, the silicon-steel sheet has a silicon-steel sheet height in the axial direction of the fan, and the ratio of the silicon-steel sheet height to the frame height is between 0.26 and 0.4.

In the embodiment of the invention, the fan has special dimensions and speed designs to provide improved heat dissipation efficiency. In particular, utilizing the dimensions and designs of the silicon-steel sheets and the corresponding magnetic part, the magnetic torque of the fan is increased, and the efficiency and the speed of the fan are therefore increased.

A detailed description is given in the following embodiments with reference to the accompanying drawings.

### BRIEF DESCRIPTION OF THE DRAWINGS

The present invention can be more fully understood by reading the subsequent detailed description and examples with references made to the accompanying drawings, wherein:

FIG. 1 is a sectional view of a fan of an embodiment of the invention;

FIG. 2 is a perspective view of the fan of the embodiment of the invention;

FIG. 3 shows a blade of the fan of the embodiment of the invention; and

FIG. 4 shows the characteristic curves of the fan of the embodiment of the invention and the characteristic curves of a conventional fan.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

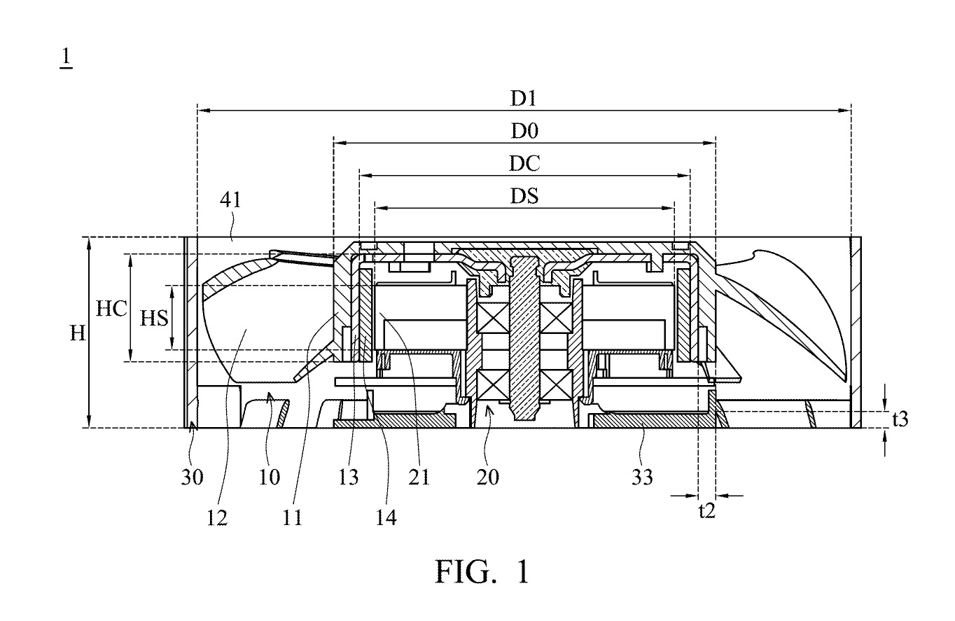

FIG. 1 is a sectional view of a fan 1 of an embodiment of the invention. The fan 1 includes a frame 30, a rotor 10 and a stator 20. The rotor 10 is received in the frame 30 and includes a magnetic part 14, a metal housing 13, a hub 11 and a plurality of blades 12. The metal housing 13 is telescoped on the magnetic part 14. The hub 11 is telescoped on the metal housing 13. Each of the blades 12 is formed on peripheral of the hub 11. The stator 20 is received in the frame 30. The stator 20 includes a plurality of silicon-steel sheets 21. The silicon-steel sheets 21 form or define a silicon-steel sheet outside diameter DS. The silicon-steel sheet outside diameter DS is greater than 42 mm. The rated speed of the fan 1 is greater than 8000 RPM.

In one embodiment of the invention, the magnetic part is a magnetic ring generally, however, can be replaced by a magnetic rubber, a magnetic belt or other magnetic elements.

In the embodiment of the invention, the fan has special dimensions and speed designs to provide improved heat dissipation efficiency. In particular, by utilizing the dimensions of the silicon-steel sheets and the corresponding magnetic part, the magnetic torque of the fan is increased, and the efficiency and the speed of the fan are therefore increased.

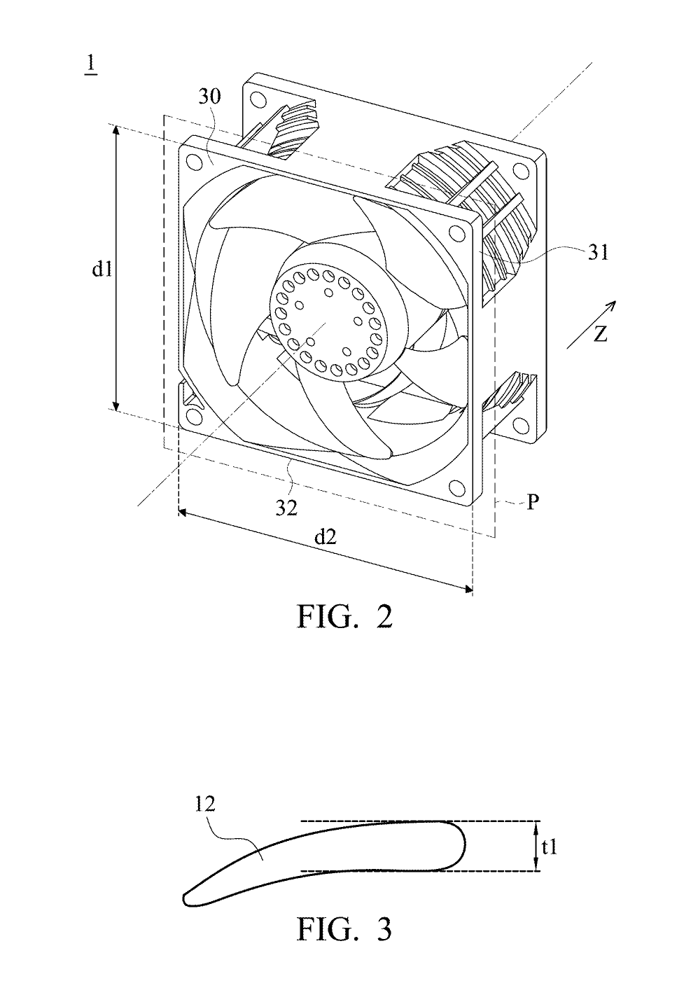

In the embodiments of the invention, the fan dimensions (width and length) are between 131 mm and 139 mm. With reference to FIG. 2, in one embodiment, the frame 30 comprises a first edge 31 and a second edge 32. The first edge 31 is perpendicular to the second edge 32. The first edge 31 and the second edge 32 are located on a plane P. The axial direction Z of the fan is perpendicular to the plane P. The first edge 31 has a first width d1, the second edge 32 has a second width d2, the first width d1 is between 131 mm and 139 mm, and the second width d2 is between 131 mm and 139 mm.

In the conventional design, a fan having dimensions of 120 mm×120 mm is restricted by power, and cannot provide sufficient heat dissipation efficiency. A fan having dimensions of or greater than 140 mm×140 mm has increased weight and blade length, which is easily broken under high-speed rotation due to structural property, and has decreased reliability that related to safety. In the embodiments of the invention in contrast, the fan dimensions (width and length) are between 131 mm and 139 mm, which has increased both efficiency and reliability. Therefore, in the embodiment of the invention, the fan has special dimensions and speed designs to solve problems with conventional designs.

In one embodiment, the first width d1 and the second width d2 are the same 134 mm. A projection of the frame 30 on the plane P is square. In another embodiment, considering the manufacturing tolerance, the tolerance between the first width and the second width is acceptable when it is less than 5%.

With reference to FIGS. 1 and 2, in one embodiment, the frame 30 has a frame height H in an axial direction Z of the fan 1, and the silicon-steel sheet 21 has a silicon-steel sheet height HS in the axial direction Z of the fan 1. The ratio (HS/H) of the silicon-steel sheet height HS to the frame height H is between 0.26 and 0.4. In this embodiment, by utilizing the dimensions and designs of the silicon-steel sheet and the corresponding magnetic part, the torque of the stator of the fan can be increased further.

With reference to FIGS. 1 and 2, in one embodiment, the frame 30 forms a flow path 41, and the flow path 41 has a path diameter D1. The ratio (DS/D1) of the silicon-steel sheet outside diameter DS to the path diameter D1 is between 0.4 and 0.5. In this embodiment, by utilizing the dimensions and designs of the silicon-steel sheet and the corresponding magnetic part, the torque of the stator of the fan can be increased further.

With reference to FIGS. 1 and 2, in one embodiment, the hub 11 has a hub diameter D0, the metal housing 13 has a metal housing height HC in the axial direction Z of the fan 1. The ratio (D0/D1) of the hub diameter D0 to the path diameter D1 is between 0.53 and 0.63. The ratio (HC/H) of the metal housing height HC to the frame height H is between 0.5 and 0.6. In this embodiment, by utilizing the dimensions and designs of the hub and the metal housing, the efficiency of the fan can improved further.

With reference to FIGS. 1 and 2, in one embodiment, the metal housing 13 has a metal housing inside diameter DC. The ratio (DC/D1) of the metal housing inside diameter DC to the path diameter D1 is between 0.45 and 0.55. In this embodiment, by utilizing the dimensions and design of the metal housing inside diameter, the efficiency of the fan can be improved further. The silicon-steel sheet and the magnetic part are cooperated to generate sufficient torque. The size and the position of the magnetic part are according to the metal housing inside diameter. Therefore, by utilizing the ratios described above, a higher or a thicker shapes of the magnetic part can be used to provide increased magnetic torque without modifying the silicon-steel sheet.

With reference to FIG. 3, in one embodiment, the thickness t1 of the blade 12 (the thickest thickness between the upper edge and the lower edge) is between 3 mm and 4.5 mm. With reference to FIG. 1, in one embodiment, the material thickness t2 of the hub 11 is between 2 mm and 3 mm. By utilizing the designs of the thickness of the blade and the material thickness of the hub, the fan has improved strength and safety for high-speed rotation. In the embodiment above, the shape of the blade 12 defines the thickness of the blade (t1), which is not meant to restrict the invention. In other embodiments, the shape of the blade 12 can be modified.

With reference to FIG. 1, in one embodiment, the material of the frame 30 is metal. In one embodiment, the frame 30 comprises a plurality of ribs or a plurality of static blades 33, and the greatest thickness t3 among the rib or the static blades 33 is greater than 1.5 mm. Similarly, by utilizing the designs of the material of the frame and the greatest thickness among the ribs or the static blades, the fan has improved strength and safety for high speed rotation. In one embodiment, the material of the frame 30 can also be plastic. Commonly, when the frame is made of plastic, the rated speed of the fan is between 5000 and 6000 RPM, and the thickness of the frame is increased about 2.5 mm to 3.0 mm in practice.

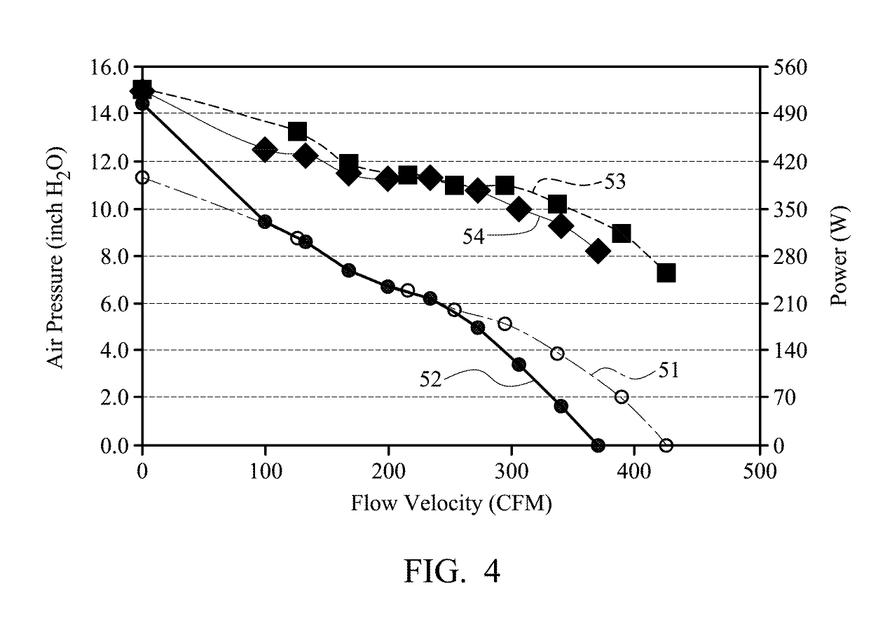

In one embodiment, the dimensions of the fan are 134 mm×134 mm×38 mm, and the rated speed of the fan is 13700 RPM. FIG. 4 shows the characteristic curves of the fan of the embodiment of the invention relative to the conventional fan. The line 51 represents the pressure-flow velocity curve of the 134 mm×134 mm×38 mm fan of the embodiment of the invention, the line 52 represents the pressure-flow velocity curve of the conventional 120 mm×120 mm×38 mm fan, the line 53 represents the power-flow velocity curve of the 134 mm×134 mm×38 mm fan of the embodiment of the invention, and the line 54 represents the power-flow velocity curve of the conventional 120 mm×120 mm×38 mm fan. As shown in FIG. 4, the fan of the embodiment of the invention provides improved efficiency. When the air flow increases, the air pressure is decreased, and there must be an optimum operating point, that is, the intersection of the fan performance curve and the system impedance curve. At the optimum operating point, the slope of the fan characteristic curve is the smallest, the variation of the system characteristic curve is lowest, and the static efficiency of the fan is the most. In this embodiment, the fan of the embodiment of the invention has a power consumption of about 540 W. In an embodiment of the invention, the performance of the fan is greater than 200 W.

Use of ordinal terms such as “first”, “second”, “third”, etc., in the claims to modify a claim element does not by itself connote any priority, precedence, or order of one claim element over another or the temporal order in which acts of a method are performed, but are used merely as labels to distinguish one claim element having a certain name from another element having the same name (but for use of the ordinal term).

While the invention has been described by way of example and in terms of the preferred embodiments, it should be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A fan, comprising:
a frame;
a rotor, received in the frame, comprising:
a magnetic part;
a metal housing, telescoped on the magnetic part;
a hub, telescoped on the metal housing; and
a plurality of blades, formed on the hub; and
a stator, received in the frame, comprising a plurality of silicon-steel sheets, wherein the silicon-steel sheets form a silicon-steel sheet outside diameter, the silicon-steel sheet outside diameter is greater than 42 mm and the fan has a rated speed that is greater than 8000 RPM.

2. The fan as claimed in claim 1, wherein the frame comprises a first edge and a second edge, the first edge is perpendicular to the second edge, the first edge and the second edge are located on a plane, the fan has an axial direction that is perpendicular to the plane, the first edge has a first width, the second edge has a second width, the first width is between 131 mm and 139 mm, and the second width is between 131 mm and 139 mm.

3. The fan as claimed in claim 1, wherein the frame has a frame height in an axial direction of the fan, the silicon-steel sheet has a silicon-steel sheet height in the axial direction of the fan, and a ratio of the silicon-steel sheet height to the frame height is between 0.26 and 0.4.

4. The fan as claimed in claim 3, wherein the frame forms a flow path, the flow path has a path diameter, and a ratio of the silicon-steel sheet outside diameter to the path diameter is between 0.4 and 0.5.

5. The fan as claimed in claim 4, wherein the hub has a hub diameter, the metal housing has a metal housing height in the axial direction of the fan, a ratio of the hub diameter to the path diameter is between 0.53 and 0.63, and a ratio of the metal housing height to the frame height is between 0.5 and 0.6.

6. The fan as claimed in claim 4, wherein the metal housing has a metal housing inside diameter, and a ratio of the metal housing inside diameter to the path diameter is between 0.45 and 0.55.

7. The fan as claimed in claim 1, wherein the blade has a thickness of between mm and 4.5 mm.

8. The fan as claimed in claim 7, wherein the hub has a material thickness of between 2 mm and 3 mm.

9. The fan as claimed in claim 1, wherein the frame comprises a plurality of ribs or a plurality of static blades, and the greatest thickness among the ribs or the static blades is greater than 1.5 mm.

10. A fan, comprising:
a frame;
a rotor, received in the frame, comprising:
a magnetic part;
a metal housing, telescoped on the magnetic part;
a hub, telescoped on the metal housing; and
a plurality of blades, formed on the hub; and
a stator, received in the frame, comprising a plurality of silicon-steel sheets, wherein the frame has a frame height in an axial direction of the fan, the silicon-steel sheet has a silicon-steel sheet height in the axial direction of the fan, and a ratio of the silicon-steel sheet height to the frame height is between 0.26 and 0.4.

11. The fan as claimed in claim 10, wherein the silicon-steel sheets form a silicon-steel sheet outside diameter, the frame forms a flow path, the flow path has a path diameter, and a ratio of the silicon-steel sheet outside diameter to the path diameter is between 0.4 and 0.5.

12. The fan as claimed in claim 11, wherein the hub has a hub diameter, the metal housing has a metal housing height in the axial direction of the fan, a ratio of the hub diameter to the path diameter is between 0.53 and 0.63, and a ratio of the metal housing height to the frame height is between 0.5 and 0.6.

13. The fan as claimed in claim 11, wherein the metal housing has a metal housing inside diameter, and a ratio of the metal housing inside diameter to the path diameter is between 0.45 and 0.55.

14. The fan as claimed in claim 10, wherein the frame comprises a first edge and a second edge, the first edge is perpendicular to the second edge, the first edge and the second edge are located on a plane, the axial direction of the fan is perpendicular to the plane, the first edge has a first width, the second edge has a second width, the first width is between 131 mm and 139 mm, and the second width is between 131 mm and 139 mm.

15. The fan as claimed in claim 14, wherein the tolerance between the first width and the second width is less than 5%.

16. The fan as claimed in claim 10, wherein the rated speed of the fan is greater than 8000 RPM.

17. The fan as claimed in claim 10, wherein the silicon-steel sheets form a silicon-steel sheet outside diameter, and the silicon-steel sheet outside diameter is greater than 42 mm.

18. The fan as claimed in claim 10, wherein the thickness of the blade is between 3 mm and 4.5 mm.

19. The fan as claimed in claim 18, wherein the material thickness of the hub is between 2 mm and 3 mm.

20. The fan as claimed in claim 10, wherein the frame comprises a plurality of ribs or a plurality of static blades, and the greatest thickness among the ribs or the static blades is greater than 1.5 mm.
